(19) United States
(12) Patent Application Publication
(10) Pub. No.: US 2014/0144691 A1
(43) Pub. Date: May 29, 2014

(54) METHOD FOR SHORTENING VIA STUB AND PRINTED CIRCUIT BOARD DESIGNED BASED ON THE METHOD

(71) Applicants: Hong Fu Jin Precision Industry (ShenZhen) Co., Shenzhen (CN); HON HAI PRECISION INDUSTRY CO., LTD., New Taipei (TW)

(72) Inventors: MING WEI, Shenzhen (CN); CHIA-NAN PAI, Tu-Cheng,New Taipei (TW); SHOU-KUO HSU, Tu-Cheng,New Taipei (TW)

(73) Assignees: HON HAI PRECISION INDUSTRY CO., LTD., New Taipei (TW); Hong Fu Jin Precision Industry (ShenZhen) Co., Shenzhen (CN)

(21) Appl. No.: 13/736,083

(22) Filed: Jan. 8, 2013

(30) Foreign Application Priority Data
Nov. 26, 2012 (CN) 201210486893.6

(51) Int. Cl. H05K 1/02; G06F 17/50

(52) U.S. Cl. CPC H05K 1/0213; G06F 17/5077
USPC 174/262; 716/126

(57) ABSTRACT

A method for shortening a via stub includes: designing a first via hole to connect signal lines of a top layer and a bottom layer of a printed circuit board; and designing a second via hole to connect signal lines of the bottom layer and one of a number of middle layers of the printed circuit board. The printed circuit board include n layers, n is an even number, and the number of the one of the number of middle layers counting top down or bottom up is less than or equal to n/2. A related printed circuit board is also provided.

### BACKGROUND

1. Technical Field

Embodiments of the present disclosure relate to methods for designing a printed circuit board (PCB) and, particularly, to a method for shortening via stub and a PCB designed according to the method.

2. Description of Related Art

Via hole design is an important phase in the design of a printed circuit board (PCB). A via stub may be generated when the PCB has a plurality of layers.

There are two common methods for removing via stubs. One is a technique of manufacturing buried via holes to remove the stubs. Another is a back-drilling technique to remove the stubs. However, these methods add to production costs, and the back-drilling technique is difficult to perform.

### BRIEF DESCRIPTION OF THE DRAWINGS

The components of the drawings are not necessarily drawn to scale, the emphasis instead being placed upon clearly illustrating the principles of the present disclosure. Moreover, in the drawings, like reference numerals designate corresponding parts throughout several views.

FIG. 1 is a schematic view showing a via stub of a via hole in a standard PCB.

FIG. 2 is a schematic view showing an added via hole employed to shorten a via stub, in accordance with an exemplary embodiment.

### DETAILED DESCRIPTION

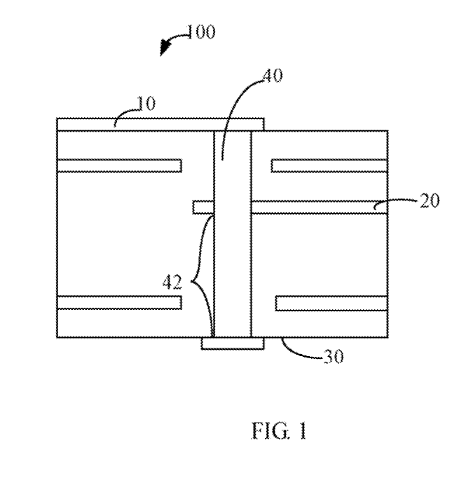

Referring to FIG. 1, a PCB 100 includes a top layer 10, a number of middle layers 20, a bottom layer 30, a via hole 40, and a via stub 42. The via hole 40 extends through the PCB 100, and the via stub 42 is from one middle layer 20 to the bottom layer 30. The PCB 100 usually includes n layers, where n is an even number. If the number of the one middle layer 20 counting from the top down or bottom up is less than or equal to n/2, then the via stub 42 is relatively longer. For example, if the one middle layer is the fifth layer from the top and n=10, then 10/2=5. So the number of the one middle layer is equal to n/2.

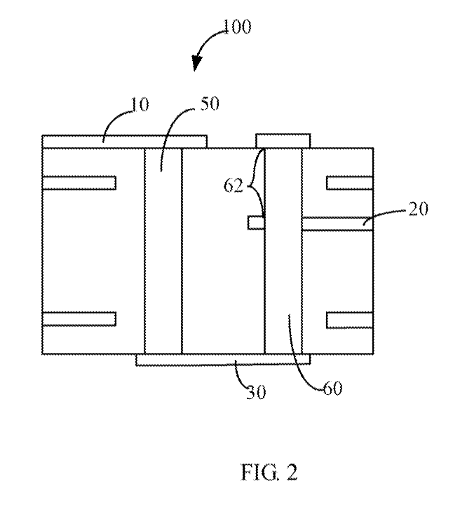

FIG. 2 is a schematic view showing an added via hole employed to shorten a via stub, in accordance with an exemplary embodiment. A first via hole 50 is designed to connect signal lines of the top layer 10 and the bottom layer 30. A second via hole 60 is designed to connect signal lines of the bottom layer 30 and one middle layer 20. In this embodiment, the number of the one middle layer 20 counting from the top down or bottom up is less than or equal to n/2.

It is clear that the via stub 62 in FIG. 2 is shorter than the via stub 42 in FIG. 1. Thus, adding a via hole according to the present method can shorten the via stub if the number of the one middle layer 20 connected to the bottom layer 30 counting from top down or bottom up is less than or equal to n/2, which can reduce production cost.

Although the present disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. A method for shortening a via stub, the method comprising:
designing a first via hole to connect signal lines of a top layer and a bottom layer of a printed circuit board; and
designing a second via hole to connect signal lines of the bottom layer and one of a plurality of middle layers of the printed circuit board, wherein the printed circuit board comprises n layers, n is an even number, and the number of the one of the plurality of middle layers counting from top down or bottom up is less than or equal to n/2.

2. A printed circuit board comprising:
a top layer;
a plurality of middle layers;
a bottom layer;
a first via hole to connect signal lines of the top layer and the bottom layer; and
a second via hole to connect signal lines of the bottom layer and one of the plurality of middle layers, wherein the printed circuit board comprises n layers, n is an even number, and the number of the one of the plurality of middle layers counting from top down or bottom up is less than or equal to n/2.
